(19) United States
(12) Patent Application Publication
(10) Pub. No.: US 2024/0106249 A1
(43) Pub. Date: Mar. 28, 2024

(54) BATTERY PACK FAILURE DIAGNOSTIC METHOD AND BATTERY PACK

(71) Applicant: Panasonic Energy Co., Ltd., Osaka (JP)

(72) Inventors: ATSUSHI SUYAMA, Osaka (JP); KAZUYA MAEGAWA, Osaka (JP); YUJI ARAI, Osaka (JP)

(21) Appl. No.: 18/264,434

(22) PCT Filed: Feb. 2, 2022
(86) PCT No.: PCT/JP2022/007204

§ 371 Date: Aug. 7, 2023

(30) Foreign Application Priority Data
Feb. 25, 2021 (JP) 2021-029199

(51) Int. Cl. H02J 7/00

(52) U.S. Cl. CPC H02J 7/00304; H02J 7/0048; H02J 7/0068

(57) ABSTRACT

A battery pack and a method of diagnosing a failure of an overcurrent detection circuit are provided to diagnosing the overcurrent detection circuit so as to maintain the overcurrent detection circuit in a safe state. A detection signal output from a current detection element connected to an output side of a battery unit is compared with a threshold value. An overcurrent is detected when the detection signal indicates an overcurrent value exceeding the threshold value. In the method, a failure of the overcurrent detection circuit is detected by inputting an overcurrent diagnostic signal to the overcurrent detection circuit.

### TECHNICAL FIELD

The present invention relates to a method of diagnosing a failure of a battery pack including an overcurrent detection circuit, and to a battery pack including the overcurrent detection circuit.

### BACKGROUND ART

A switching element, such as a field-effect transistor (FET), is connected to an output side of a battery pack to enhance the safety of the battery pack. The battery pack includes a switching element which cuts off a current in an abnormality. When overcurrent is detected, the switching element is turned off to cut off the overcurrent. In the battery pack, a circuit which detects overcurrent turns off the switching element to cut off the current. When overcurrent occurs, the battery pack reliably cuts off the current, thereby preventing the adverse effects caused by the overcurrent. Methods have been developed to prevent the adverse effects of the overcurrent. For example, PTL 1 discloses a method of detecting that a switching element which cuts off overcurrent operates normally. In the method disclosed in PTL 1, a failure is determined without turning off the switching element. However, the method fails to diagnose a failure of an overcurrent detection circuit which controls the turning on and off of the switching element, and hardly maintains the battery pack in a safe state.

Citation List

### PATENT LITERATURE

PTL1: Japanese: Patent Laid-Open: Publication N. 2016-118571

### SUMMARY OF THE INVENTION

### Technical Problem

The present invention is to solve the above drawback. An object of the present invention is to provide an overcurrent detection circuit failure diagnostic method and a battery pack which are capable of maintaining an overcurrent detection circuit in a safe state by diagnosing the overcurrent detection circuit.

### Solution to Problem

A method of diagnosing a failure of a battery pack according to an aspect of the present invention is a method of diagnosing a failure of an overcurrent detection circuit of the battery pack. The overcurrent detection circuit is configured to compare, with a threshold value, a detection signal output from a current detection element connected to an output side of a battery unit and to determine an overcurrent when the detection signal indicates an overcurrent value exceeding the threshold value. In this method, a failure of the overcurrent detection circuit is determined by inputting an overcurrent diagnostic signal to the overcurrent detection circuit.

A battery pack according to an aspect of the present invention includes a battery unit, a switching element connected in series with the battery unit, a current detection element connected in series with the battery unit, an overcurrent detection circuit configured to: determine an overcurrent based on an output voltage of the current detection element; and turn off the switching element in an overcurrent state, and a diagnostic circuit configured to diagnose a failure of the overcurrent detection circuit. The diagnostic circuit includes an overcurrent simulation circuit configured to input an overcurrent diagnostic signal to the overcurrent detection circuit. The diagnostic circuit is configured to determine the failure of the overcurrent detection circuit based on the overcurrent diagnostic signal output from the overcurrent simulation circuit to the overcurrent detection circuit.

### Advantageous Effect of Invention

The failure diagnostic method and the battery pack described above maintain the battery pack in a safe state by diagnosing whether or not the overcurrent detection circuit operates normally.

### BRIEF DESCRIPTION OF THE DRAWINGS

FIG. 1 is a schematic configuration diagram of a battery pack according to an exemplary embodiment of the present invention.

FIG. 2 is a circuit diagram of a voltage amplifier circuit.

FIG. 3 is a flowchart of diagnosing a failure of an overcurrent detection circuit while the battery pack is not used.

### DESCRIPTION OF EMBODIMENT

A method of diagnosing a failure of a battery pack according to an aspect of the present invention is a method of diagnosing a failure of an overcurrent detection circuit of the battery pack. The overcurrent detection circuit is configured to compare, with a threshold value, a detection signal output from a current detection element connected to an output side of a battery unit and to determine an overcurrent when the detection signal indicates an overcurrent value exceeding the threshold value. In the method, a failure of the overcurrent detection circuit is determined by inputting an overcurrent diagnostic signal to the overcurrent detection circuit.

The above-described method provides an advantageous effect maintaining the battery pack in a safe state by diagnosing whether or the overcurrent detection circuit operates normally with a simple circuit configuration. This is because a failure of the overcurrent detection circuit is diagnosed with a simple circuit configuration in which an overcurrent diagnostic signal is input to the overcurrent detection circuit without causing overcurrent to flow through the battery.

In the method according to another aspect of the present invention, the failure of the overcurrent detection circuit is determined in an unused state of the battery unit in which the battery unit is not charged or discharged.

In the method described above, the failure of the overcurrent detection circuit is determined in a non-use state in which no power is supplied to the battery unit, so that the failure of the overcurrent detection circuit can be diagnosed accurately,

In the failure diagnostic method of a battery pack according to another aspect of the present invention, the unused state is determined by detecting, by a microcomputer, an output signal from the current detection element.

In the failure diagnostic method of a battery pack according to another aspect of the present invention, the current detection element is a current detection resistor. The failure of the overcurrent detection circuit is determined by inputting an overcurrent diagnostic voltage to the current detection resistor.

In the failure diagnostic method of a battery pack according to another aspect of the present invention, a comparator compares an output signal of the current detection element with the threshold value. The overcurrent detection circuit determines an overcurrent when the output signal exceeds the threshold value.

The failure diagnostic method described above provides an advantageous effect that a failure of the overcurrent detection circuit is determined in an extremely short period. The overcurrent is promptly detected by the overcurrent detection circuit, and the switching element is instantaneously turned off to cut off the overcurrent. The overcurrent is detected in a short period of time, because, instead of converting the output of the current detection element into a digital signal and performing, the microcomputer performs arithmetic processing to determine overcurrent. The output signal of the current detection element is input to the comparator, and the comparator compares the signal with a threshold value to diagnose overcurrent instantaneously.

In the failure diagnostic method of a battery pack according to another aspect of the present invention, the overcurrent diagnostic signal is a pulse signal of an overcurrent diagnostic voltage having a predetermined pulse width,

The failure diagnostic method described above provides an advantageous effect that the failure is determined in a short period of time by determining the failure of the overcurrent detection circuit with a pulse signal.

In the failure diagnostic method of a battery pack according to another aspect of the present invention, a switching element connected in series with the battery unit is turned off upon detecting the failure of the overcurrent detection circuit.

The failure diagnostic method of a battery pack described above provides an advantageous effect that the switching element connected in series with the battery unit is turned off when the overcurrent detection circuit is determined to have a failure. Hence, the battery pack maintains in a safe state while avoiding continuous use of the battery pack.

A battery pack according to an aspect of the present invention includes a battery unit, a switching element connected in series with the battery unit, a current detection element connected in series with the battery unit, an overcurrent detection circuit configured to: determine an overcurrent based on an output voltage of the current detection element; and turn off the switching element in an overcurrent state, and a diagnostic circuit configured to diagnose a failure of the overcurrent detection circuit. The diagnostic circuit includes an overcurrent simulation circuit configured to input an overcurrent diagnostic signal to the overcurrent detection circuit. The diagnostic circuit is configured to determine the failure of the overcurrent detection circuit based on the overcurrent diagnostic signal output from the overcurrent simulation circuit to the overcurrent detection circuit.

The battery pack described above provides an advantageous effect maintaining in a safe state by diagnosing the overcurrent detection circuit with a simple circuit configuration. This is because it is not necessary to cause overcurrent to flow to diagnose a failure of the overcurrent detection circuit, and the failure of the overcurrent detection circuit is diagnosed with a simple circuit configuration in which the overcurrent simulation circuit inputs an overcurrent diagnostic signal to the overcurrent detection circuit.

In the battery pack according to another aspect of the present invention, while the battery pack is in an unused state, the diagnostic circuit is configured to output the overcurrent diagnostic signal to the overcurrent detection circuit to determine the failure of the overcurrent detection circuit.

Since the battery pack described above diagnoses the failure of the overcurrent detection circuit in the unused state, the failure of the overcurrent detection circuit is be diagnosed more accurately.

In the battery pack according to another aspect of the present invention, the diagnostic circuit includes a microcomputer configured to detect the unused state of the battery pack.

In the battery pack according to another aspect of the present invention, the current detection element is a current detection resistor. The overcurrent detection circuit includes a voltage amplifier circuit configured to amplify a voltage of the current detection resistor, and a determination circuit configured to compare an output voltage of the voltage amplifier circuit with a threshold value to determine the overcurrent.

In the battery pack according to another aspect of the present invention, the determination circuit includes a comparator configured to compare the output voltage of the voltage amplifier circuit with the threshold value.

The battery pack described above provides an advantageous effect of diagnosing a failure of the overcurrent detection circuit in real time. Overcurrent is promptly detected, and the switching element is instantaneously turned off to cut off the overcurrent. The overcurrent is detected promptly because, instead of converting the output of the current detection element into a digital signal and performing, by the microcomputer, arithmetic processing to determine overcurrent, the output signal of the current detection element is input to the comparator and the comparator compares the signal with a threshold value to diagnose overcurrent instantaneously.

In the battery pack according to another aspect of the present invention, wherein the overcurrent simulation circuit includes a pulse generation circuit configured to output a pulse signal of an overcurrent diagnostic voltage.

In the battery pack according to another aspect of the present invention, the pulse generation circuit is configured to output the overcurrent diagnostic signal to the overcurrent detection circuit for diagnosis. The overcurrent diagnostic signal has a pulse waveform with a pulse width 0.1 μsec or longer and 1 sec or shorter.

Hereinafter, the present invention will be described in detail with reference to the drawings. It should be noted that in the following description, teens indicating a specific direction or position (for example, “upper”, “lower”, and other terms including those terms) are used as necessary, but the use of these terms is to facilitate the understanding of the invention with reference to the drawings, and the meaning of these terms does not limit the technical scope of the present invention. In addition, the parts having the same reference numerals appearing in a plurality of drawings indicate the same or equivalent parts or members.

Furthermore, the embodiment described below shows a specific example of the technical idea of the present invention, and does not limit the present invention to the following. In addition, unless otherwise specified, the dimensions, materials, shapes, relative arrangements, and the like of the structural elements described below are not intended to limit the scope of the present invention only thereto, but intended to be exemplified. In addition, the details described in the embodiment or example can be applied to other embodiments or examples. In addition, the size, positional relationship, and the like of the members illustrated in the drawings may be exaggerated in order to clarify the explanation.

### Exemplary Embodiment 1

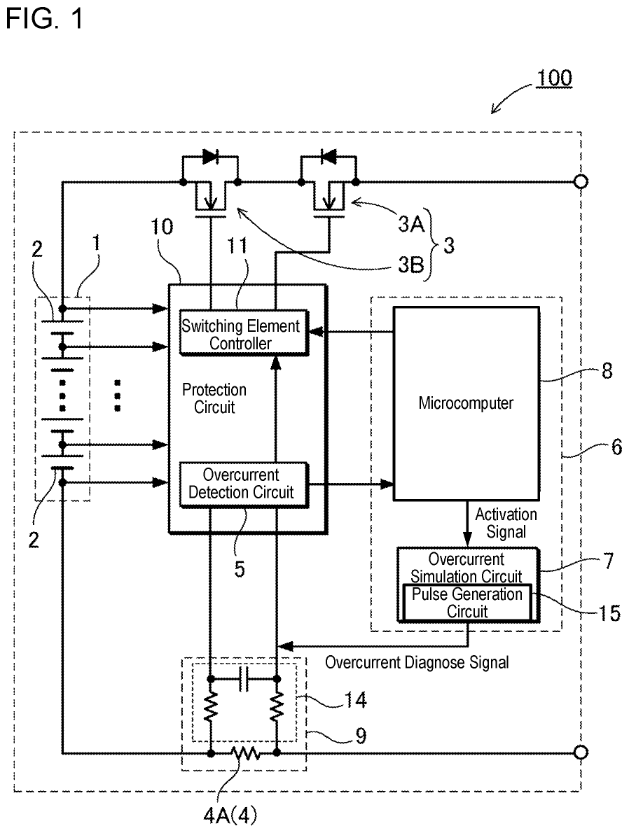

Battery pack 100 illustrated in FIG. 1 includes: battery unit 1 including battery cells 2, switching element 3 connected in series with battery unit 1, current detection element 4 configured to detect current flowing through battery unit 1, protection circuit 10 including overcurrent detection circuit 5 configured to turn on and off switching element 3 in response to a signal from current detection element 4 when overcurrent occurs, and diagnostic circuit 6 configured to diagnose a failure of overcurrent detection circuit 5 of protection circuit 10. Protection circuit 10 includes, in addition to overcurrent detection circuit 5, switching element controller 11 configured to detect overcurrent and control switching element 3. Diagnostic circuit 6 includes microcomputer 8 configured to determine an unused state of battery pack 100 and overcurrent simulation circuit 7 configured to output an overcurrent diagnostic signal to overcurrent detection circuit 5 at the timing of diagnosing the failure of overcurrent detection circuit 5 based on the signal from microcomputer 8,

In battery pack 100 described above, microcomputer 8 determines the unused state of battery pack 100, and overcurrent simulation circuit 7 outputs an overcurrent diagnostic signal to overcurrent detection circuit 5 in response to an activation signal from microcomputer 8, so that a failure of overcurrent detection circuit 5 is determined. Overcurrent simulation circuit 7 outputs an overcurrent diagnostic signal to an input side of overcurrent detection circuit 5 which is an output side of current detection element 4. In battery pack 100, a voltage higher than or equal to the voltage generated when overcurrent flows through current detection element 4 is input to current detection element 4 to create a state where overcurrent flows through current detection element 4, so that a failure of overcurrent detection circuit 5 is determined.

Battery Unit 1

Battery unit 1 includes battery cells 2 connected in series or in parallel with one another. A non-aqueous electrolyte secondary battery, such as a lithium ion secondary battery having a large charge and discharge capacity, is suitable for each battery cell 2. However, battery cell 2 according to the present invention is not limited to the lithium ion secondary battery, but may be any secondary battery currently available or to be developed in the future, such as a nickel hydride battery or an all-solid-state battery.

Switching Element 3

A semiconductor switching element, such as a FET or a transistor, may be used as switching element 3, but an FET is preferably used. A FET has features that the on-resistance of the FET is lower than the on-resistance of a transistor, and the power loss in an ON state is small. In battery pack 100 illustrated in FIG. 1, discharging switching element 3A which cuts off discharging current and charging switching element 3B which cuts off charging current are connected in series to each other. A FET is turned on and off based on a gate voltage, and a transistor is turned on and off based on base current.

Current Detection Element 4

Current detection element 4 may be implemented by current detection resistor 4A connected in series with battery unit 1. A voltage across current detection resistor 4A increases in proportion to current. Since the product of the electrical resistance and the current of current detection resistor 4A is the voltage across current detection resistor 4A, current may be detected based on the voltage across current detection resistor 4A. Since current detection resistor 4A is connected in series with battery unit 1 and consumes power, the electric resistance is determined to be as low as possible to reduce power consumption. Since the voltage induced across current detection resistor 4A with a low electric resistance is low, the voltage is amplified by a differential amplifier, so that current is detected. Instead of current detection resistor 4A, current detection element 4 may be implemented by any other elements configured to output a voltage increasing in proportion to current, such as a current detection element which detects magnetic flux density and which is configured to output an output voltage increases in proportion to current.

Protection Circuit 10

Protection circuit 10 includes overcurrent detection circuit 5 configured to compare the output signal obtained by amplifying the voltage of current detection element 4 with a threshold value to determine overcurrent, and switching element controller 11 configured to turn on and off switching element 3 in response to a signal from overcurrent detection circuit 5.

Overcurrent Detection Circuit 5

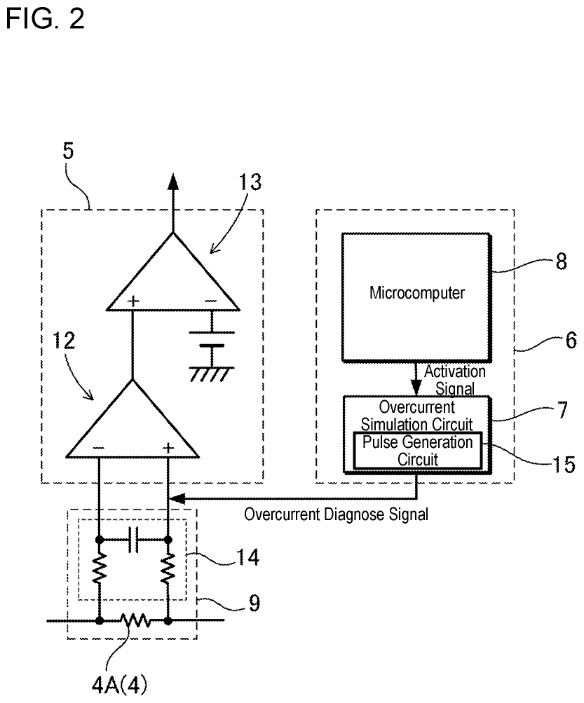

Overcurrent detection circuit 5 includes voltage amplifier circuit 12 configured to amplify the voltage across current detection resistor 4A, and determination circuit 13 configured to compare the output signal of voltage amplifier circuit 12 with the threshold value to determine overcurrent. Since current detection resistor 4A has a low resistance in order to reduce power consumption, the generated voltage is low with respect to flowing current. This is because the generated voltage is proportional to the product of the electrical resistance and the current. Voltage amplifier circuit 12 amplifies the generated low voltage, and outputs the amplified voltage. FIG. 2 illustrates a circuit diagram of voltage amplifier circuit 12 illustrated in FIG. 1. Voltage amplifier circuit 12 illustrated in MG, 2 is a differential amplifier, and includes inverting and noninverting input terminals connected across current detection resistor 4A. Current detection circuit 9 includes low-pass filter 14 connected between the input terminal and current detection resistor 4A. The resistance value of low-pass filter 14 is determined to be an electric resistance which is sufficiently lower than the input impedance of current detection circuit 9 and is sufficiently higher than the electric resistance of current detection resistor 4A, in order that an overcurrent diagnostic signal from overcurrent simulation circuit 7 to be described later may be input to overcurrent detection circuit 5 without lowering the signal Current detection circuit 9 with an input terminal connected to low-pass filter 14 is configured to input both the overcurrent diagnostic signal from overcurrent simulation circuit 7 and the generated voltage of current detection resistor 4A to overcurrent detection circuit 5 without lowering the signal and the voltage, and accurately detects the current while accurately diagnosing a failure. In addition, overcurrent simulation circuit 7 may accurately diagnose a failure and accurately detects the current without a circuit which reduces the output impedance.

Determination circuit 13 compares the output signal of voltage amplifier circuit 12 with the threshold value to detect overcurrent. The threshold value determines the lowest current at which overcurrent is determined. FIG. 2 illustrates an exemplary circuit diagram of overcurrent detection circuit 5 illustrated in FIG. 1. As illustrated in FIG. 2, a comparator is preferably used for determination circuit 13. The comparator compares the output voltage of voltage amplifier circuit 12 with a reference voltage determining the threshold value to determine overcurrent. The reference voltage of the comparator is determined to be the output voltage output from current detection circuit 9 while state where the lowest current at which overcurrent is determined flows through current detection resistor 4A. The comparator illustrated in FIG. 2 includes a noninverting input terminal connected to the output of voltage amplifier circuit 12 and an inverting input terminal connected to a positive side of the reference voltage. When the output voltage of voltage amplifier circuit 12 is higher than the reference voltage, that is, when overcurrent flows through current detection resistor 4A, the comparator outputs a High positive signal as an overcurrent detection signal. The overcurrent detection signal is output to microcomputer 8 as a flag.

For failure diagnosis, overcurrent detection circuit 5 operates both while battery pack 100 is in the used state and in the unused state. While battery pack 100 is in the used state, overcurrent flowing through current detection element 4 allows overcurrent detection circuit 5 to output an overcurrent detection signal. While battery pack 100 is in the unused state, when diagnosing a failure of overcurrent detection circuit 5, overcurrent detection circuit 5 outputs an overcurrent detection signal as a flag to microcomputer 8 while overcurrent detection circuit 5 operates normally. Since determination circuit 13 of the comparator compares the output signal of voltage amplifier circuit 12 with the threshold value in real time, determination circuit 13 promptly outputs an overcurrent detection signal when the output signal exceeds the threshold value. Accordingly, while battery pack 100 is in the used state, overcurrent is detected in an extremely short period of time and the current of battery pack 100 is promptly cut off. Moreover, when diagnosing a failure of overcurrent detection circuit 5 while battery pack 100 is in the unused state, failure diagnosis can be performed in a short period of ti m e.

Switching Element Controller 11

Upon receiving the overcurrent detection signal input from overcurrent detection circuit 5 while battery pack 100 is in the used state, switching element controller 11 switches switching element 3 from turning on to turning off. Battery pack 100 illustrated in FIG. 1 includes discharging switching element 3A and charging switching element 3B which are connected in series to each other. Hence, in response to the overcurrent detection signal, switching element controller 11 turns off discharging switching element 3A, or switches both discharging switching element 3A and charging switching element 3B from turning on to turning off to cut off the overcurrent of battery unit 1. While battery pack 100 is in the used state, switching element controller 11 promptly turns off switching element 3 in response to the overcurrent detection signal output from determination circuit 13 of overcurrent detection circuit 5 without using microcomputer 8. While battery pack 100 is in the unused state, switching element controller 11 turns off switching element 3 in response to an OFF signal input from microcomputer 8. Upon detecting that overcurrent detection circuit 5 does not operate normally, microcomputer 8 causes switching element controller 11 to turn off switching element 3.

Diagnostic Circuit 6

Diagnostic circuit 6 includes overcurrent simulation circuit 7 configured to input an overcurrent diagnostic signal to overcurrent detection circuit 5 to diagnose a failure of overcurrent detection circuit 5. Overcurrent simulation circuit 7 shown in FIG. 1 and FIG. 2 is connected to current detection element 4 via low-pass filter 14. The resistance value of low-pass filter 14 is set to an electric resistance which is sufficiently higher than the electrical resistance of current detection resistor 4A and sufficiently lower than the input impedance of voltage amplifier circuit 12 provided on the input side of overcurrent detection circuit 5, and is determined to range, for example, from 1 kΩ to 100 kΩ,

Overcurrent simulation circuit 7 is configured to output a pulse signal of an overcurrent diagnostic voltage having a predetermined pulse width as the overcurrent diagnostic signal. Overcurrent simulation circuit 7 illustrated in FIG. 1 and FIG. 2 includes pulse generation circuit 15 configured to output a pulse signal of overcurrent diagnostic voltage. For example, pulse generation circuit 15 outputs an overcurrent diagnostic signal having a pulse waveform with a time width of 0.1 μsec or longer and 1 sec or shorter to the overcurrent detection circuit.

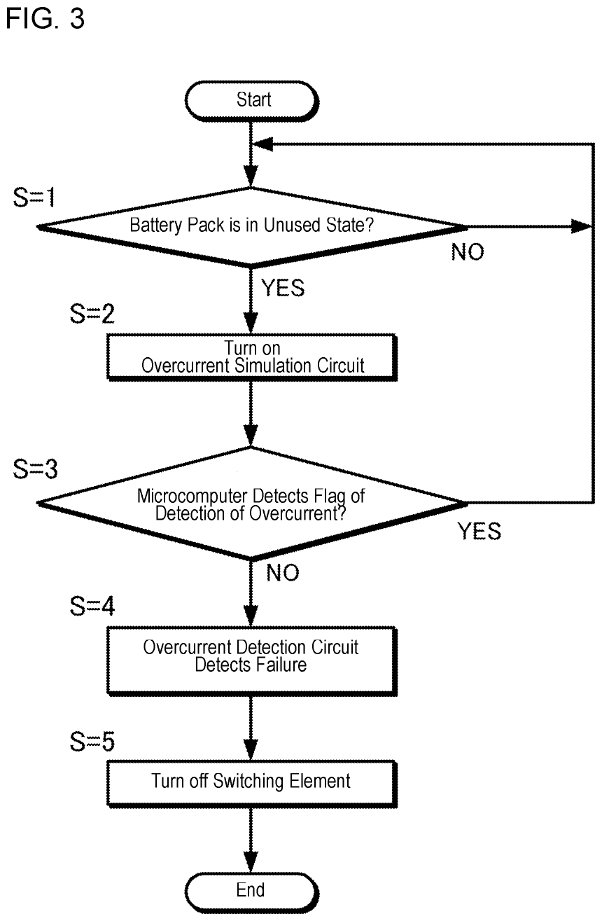

Diagnostic circuit 6 shown in FIG. 1 further includes microcomputer 8. Microcomputer 8 detects the unuse state in which battery pack 100 is not used, and diagnoses a failure of overcurrent detection circuit 5. Battery pack 100 in which the unused state is detected and the failure of overcurrent detection circuit 5 is determined is configured to determine the failure of overcurrent detection circuit 5 without affecting the normal used state. For example, microcomputer 8 determines the unused state by detecting that battery unit 1 has not been charged or discharged for a predetermined period of time. Microcomputer 8 diagnoses the failure of overcurrent detection circuit 5 in accordance with the flowchart in FIG. 3 while battery pack 100 is in the unuse state. Microcomputer S turns on overcurrent simulation circuit 7 in the unused state to diagnose a failure of overcurrent detection circuit 5 in accordance with the following flowchart.

Step S=1

In this step, microcomputer 8 determines whether battery pack 100 is in the unuse state or not. When microcomputer 8 determines that battery pack 100 is in the unused state, the process proceeds to the next step. When battery pack 100 is not in the unused state, this step is repeated.

Step 5=2

When battery pack 100 is in the unused state, overcurrent simulation circuit 7 is turned on in this step, and overcurrent simulation circuit 7 inputs an overcurrent diagnostic signal to overcurrent detection circuit 5. Overcurrent detection circuit 5 to which the overcurrent diagnostic signal has been input outputs an overcurrent detection signal and outputs a flag to microcomputer 8 when overcurrent detection circuit 5 is in a normal operating state. Overcurrent detection circuit 5 in the normal operating state outputs the overcurrent detection signal in response to the overcurrent diagnostic signal. However, overcurrent detection circuit 5 which is not in a normal operating state does not output the overcurrent detection signal as a flag in response to the overcurrent diagnostic signal. Hence, microcomputer 8 determines whether overcurrent detection circuit 5 is in the normal operating state or has a failure by detection of the flag of the overcurrent detection signal.

Steps 5=3 to S=5

When overcurrent detection circuit 5 is in the normal operating state and microcomputer 8 detects the flag from overcurrent detection circuit 5, the process jumps to step S=1, and executes the loop of S=1 to S=3, and the failure diagnosis of overcurrent detection circuit 5 is repeated in Step S=2. When overcurrent detection circuit S is not in the normal operating state, microcomputer 8 cannot detect the flag. The process then proceeds to the next step S=4, and microcomputer 8 determines that overcurrent detection circuit 5 has a failure. When overcurrent detection circuit 5 is determined to have a failure, the process proceeds to step S=5, and microcomputer 8 turns off switching element 3 to cut off the current of battery unit 1.

While battery pack 100 of the battery is in the used state, switching element 3 is turned off in response to the overcurrent detection signal output from determination circuit 13 of overcurrent detection circuit 5. While battery pack 100 is in the unused state, microcomputer 8 detects that overcurrent detection circuit 5 does not output the overcurrent detection signal, and switching element controller 11 turns off switching element 3. This is because while battery pack 100 is in the used state, it is necessary to turn off switching element 3 in response to the overcurrent detection signal to cut off the overcurrent at the timing when charging and discharging current flows through battery unit 1. But while battery pack 100 is in the unused state, at the timing of diagnosing a failure of overcurrent detection circuit 5, overcurrent detection circuit 5 is determined to have a failure in a state where the overcurrent detection signal is not output, and the current of battery unit 1 is cut off.

### INDUSTRIAL APPLICABILITY

The present invention relates to a battery pack which includes an overcurrent detection circuit, and which can be used for various purposes. The battery pack can be used safely and securely by diagnosing a failure of the overcurrent detection circuit.

### REFERENCE MARKS IN THE DRAWINGS

100 battery pack
1 battery unit
2 battery cell
3 switching element
3A discharging switching element
3B charging switching element
4 current detection element
4A current detection resistor
5 overcurrent detection circuit
6 diagnostic circuit
7 overcurrent simulation circuit
8 microcomputer
9 current detection circuit
10 protection circuit
11 switching element controller
12 voltage amplifier circuit
13 determination circuit
14 low-pass filter
15 pulse generation circuit

1. A method of diagnosing a failure of a battery pack including an overcurrent detection circuit, the overcurrent detection circuit being configured to compare, with a threshold value, a detection signal output from a current detection element connected to an output side of a battery unit and to determine an overcurrent when the detection signal indicates an overcurrent value exceeding the threshold value, the method comprising:
determining a failure of the overcurrent detection circuit by inputting an overcurrent diagnostic signal to the overcurrent detection circuit.

2. The method of claim 1, wherein said determining the failure of the overcurrent detection circuit comprises determining the failure of the overcurrent detection circuit in an unused state of the battery unit in which the battery unit is not charged or discharged.

3. The method of claim 2, further comprising
determining the unused state by detecting, by a microcomputer, an output signal from the current detection element.

4. The method of claim 1, wherein
the current detection element is a current detection resistor, and
said determining the failure of the overcurrent detection circuit comprising determining the failure of the overcurrent detection circuit by inputting an overcurrent diagnostic voltage to the current detection resistor.

5. The method of claim 1, further comprising
comparing, by a comparator, an output signal of the current detection element with the threshold value; and
determining, by the overcurrent detection circuit, an overcurrent when the output signal exceeds the threshold value.

6. The method of claim 1, wherein the overcurrent diagnostic signal is a pulse signal of an overcurrent diagnostic voltage having a predetermined pulse width.

7. The method of claim 1, further comprising
turning off a switching element connected in series with the battery unit upon detecting the failure of the overcurrent detection circuit.

8. A battery pack comprising:
a battery unit;
a switching element connected in series with the battery unit;
a current detection element connected in series with the battery unit;
an overcurrent detection circuit configured to
determine an overcurrent based on an output voltage of the current detection element, and
turn off the switching element in an overcurrent state; and
a diagnostic circuit configured to diagnose a failure of the overcurrent detection circuit, wherein
the diagnostic circuit includes an overcurrent simulation circuit configured to input an overcurrent diagnostic signal to the overcurrent detection circuit, and
the diagnostic circuit is configured to determine the failure of the overcurrent detection circuit based on the overcurrent diagnostic signal output from the overcurrent simulation circuit to the overcurrent detection circuit.

9. The battery pack of claim 8, wherein, while the battery pack is in an unused state, the diagnostic circuit is configured to output the overcurrent diagnostic signal to the overcurrent detection circuit to determine the failure of the overcurrent detection circuit.

10. The battery pack of claim 9, wherein the diagnostic circuit includes a microcomputer configured to detect the unused state of the battery pack.

11. The battery pack of claim 8, wherein
the current detection element is a current detection resistor, and
the overcurrent detection circuit includes:
a voltage amplifier circuit configured to amplify a voltage of the current detection resistor; and
a determination circuit configured to compare an output voltage of the voltage amplifier circuit with a threshold value to determine the overcurrent.

12. The battery pack of claim 11, wherein the determination circuit includes a comparator configured to compare the output voltage of the voltage amplifier circuit with the threshold value.

13. The battery pack of claim 8, wherein the overcurrent simulation circuit includes a pulse generation circuit configured to output a pulse signal of an overcurrent diagnostic voltage.

14. The battery pack of claim 13, wherein the pulse generation circuit is configured to output the overcurrent diagnostic signal to the overcurrent detection circuit for diagnosis, the overcurrent diagnostic signal having a pulse waveform with a pulse width 0.1 μsec or longer and 1 sec or shorter.
